(19) United States
(12) Patent Application Publication
(10) Pub. No.: US 2025/0183237 A1
(43) Pub. Date: Jun. 5, 2025

(54) PACKAGE STRUCTURE INCLUDING A BACKSIDE METAL FILM ON A SEMICONDUCTOR DIE AND A THERMALLY CONDUCTIVE UNDERFILL LAYER ON THE BACKSIDE METAL FILM AND METHODS OF FORMING THE SAME

(71) Applicant: Taiwan Semiconductor Manufacturing Company Limited, Hsinchu (TW)

(72) Inventors: Chih-Chien Pan, Taipei City (TW); Pu Wang, Hsinchu City (TW); Li-Hui Cheng, New Taipei City (TW); Ying-Ching Shih, Hsinchu City (TW)

(21) Appl. No.: 18/526,086

(22) Filed: Dec. 1, 2023

(51) Int. Cl. H01L 25/10; H01L 21/48; H01L 23/00; H01L 23/31; H01L 23/373; H01L 23/498; H10B 80/00

(52) U.S. Cl. CPC H01L 25/105; H01L 21/4853; H01L 23/3107; H01L 23/3737; H01L 23/49822; H01L 24/16; H01L 24/27; H01L 24/29; H01L 24/32; H01L 24/73; H10B 80/00; H01L 24/08; H01L 24/48; H01L 2224/08235; H01L 2224/16227; H01L 2224/16235; H01L 2224/27848; H01L 2224/29005; H01L 2224/29124; H01L 2224/29139; H01L 2224/29144; H01L 2224/29147; H01L 2224/32225; H01L 2224/48227; H01L 2224/73204; H01L 2225/1023; H01L 2225/1058; H01L 2225/1094; H01L 2924/1436

(57) ABSTRACT

A package structure includes a lower package including a first semiconductor die including a backside metal film on a backside of the first semiconductor die, an upper package attached to the lower package and electrically coupled to the lower package, and a thermally conductive underfill layer between the lower package and the upper package and contacting the backside metal film.

### BACKGROUND

A package structure including stacked semiconductor packages may include a complex thermal path giving rise to a potential for heat accumulation. Heat dissipation in the package structure may present several concerns. The most immediate concern is the stacking effect itself. Placing multiple semiconductor packages on top of each other may lead to a cumulative heat buildup. The heat generated by active components in both the first package and the second package may accumulate, potentially resulting in temperature levels that are higher than those in single-package configurations.

Another concern may be that the stacking of semiconductor packages may also introduce additional thermal resistance between the active components and the external environment. In order to escape, generated heat may have to traverse through multiple layers of materials, such as the substrates, interconnects and solder joints before the generated may be dissipated. This increased thermal resistance may result in higher operating temperatures and reduced overall thermal performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to various embodiments.

FIG. 1B is a plan view (top-down view) of a lower package in the package structure according to one or more embodiments.

FIG. 1C is a detailed cross-sectional view of a backside metal film and thermally conductive underfill layer in the package structure according to one or more embodiments.

FIG. 2A illustrates an intermediate structure including a sintered metal layer according to one or more embodiments.

FIG. 2B illustrates the intermediate structure including the sintered metal layer applied to a surface of the semiconductor layer according to one or more embodiments.

FIG. 2C illustrates the intermediate structure during curing of the sintered metal layer in an oven according to one or more embodiments.

FIG. 2D illustrates the first semiconductor die including the backside metal film according to one or more embodiments.

FIG. 3A is a vertical cross-sectional view of an intermediate structure including a seed layer on an adhesive layer according to one or more embodiments.

FIG. 3B is a vertical cross-sectional view of an intermediate structure including a photoresist layer according to one or more embodiments.

FIG. 3C is a vertical cross-sectional view of an intermediate structure including the through vias according to one or more embodiments.

FIG. 3D is a vertical cross-sectional view of an intermediate structure including the through vias according to one or more embodiments.

FIG. 3E is a vertical cross-sectional view of an intermediate structure including the first semiconductor die according to one or more embodiments.

FIG. 3F is a vertical cross-sectional view of an intermediate structure including the lower encapsulation layer according to one or more embodiments.

FIG. 3G is a vertical cross-sectional view of an intermediate structure including the lower encapsulation layer after performing the planarization process, according to one or more embodiments.

FIG. 3H is a vertical cross-sectional view of an intermediate structure including the frontside RDL structure, according to one or more embodiments.

FIG. 3I is a vertical cross-sectional view of an intermediate structure including the solder balls, according to one or more embodiments.

FIG. 3J is a vertical cross-sectional view of an intermediate structure on a carrier tape, according to one or more embodiments.

FIG. 3K is a vertical cross-sectional view of an intermediate structure including the upper package, according to one or more embodiments.

FIG. 3L is a vertical cross-sectional view of the intermediate structure including the thermally conductive underfill layer according to one or more embodiments.

FIG. 3M is a vertical cross-sectional view of the completed package structure after dicing according to one or more embodiments.

FIG. 4 is a flow chart illustrating a method of forming a package structure, according to one or more embodiments.

FIG. 5 is a vertical cross-sectional view of the package structure having a first alternative design according to one or more embodiments.

FIG. 6 is a vertical cross-sectional view of the package structure having a second alternative design according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In a related package structure including an upper package on a lower package, the lower package may include a semiconductor die including a die attach film. An underfill layer may be formed between the upper package and the lower package.

The die attach film may have a low thermal conductivity (e.g., k<5 W/m*k). The die attach film may, therefore, be unable to efficiently dissipate heat from a semiconductor die. Heat trapped or accumulated in a semiconductor die (e.g., silicon die) may result in poor device performance or even worse, electrical failure of the semiconductor die post reliability tests. In addition, the die attach film may include a protrusion extending from the semiconductor die. The protrusion may result in a high stress or crack initial point in the lower package.

At least one embodiment of the present disclosure may include an innovative package structure having a high thermal dissipation. Various embodiment package structures may include an upper package on a lower package. Various embodiment package structures may provide a high thermal dissipation solution especially in a compact design for mobile access point (AP), radio frequency (RF) and integrated circuit (IC) applications. The package structure may also provide a low-cost approach by attaching a high-k film directly on a semiconductor die instead of performing a dry etch to remove a die attach film on the semiconductor die, and then dispensing a high-k underfill material on the etched surface.

The package structure may replace the presently used die attach film with a high thermal conductivity (e.g., k>20 W/m*k) backside metal film. The backside metal film may provide a better thermal dissipation path between the semiconductor die in the lower package and the upper package. The backside metal film may have a good adhesion to semiconductor material (e.g., silicon). In contrast to the die attach film, the backside metal film may not protrude from a sidewall of the semiconductor die. The backside metal film may be formed on a semiconductor layer of the semiconductor die and have a width less than or equal to a width of the semiconductor layer. The backside metal film may have a thickness less than or equal to 20 μm.

A high thermal conductivity backside metal film may be achieved by using, for example, a sintered metal film. The sintered metal film may include metal particles (e.g., metal powder, metal flakes, etc.) sintered by thermal curing. The sintered metal particles (e.g., metal filler) may include random shapes. The sintered metal particles may have a width and length (e.g., diameter) of less than 100 μm. The sintered metal particles may include, for example, copper, silver, aluminum or gold.

The package structure may also include a high thermal conductivity (e.g., k>20 W/m*k) underfill (high-k UF) material layer between the upper package and the lower package. Heat generated from semiconductor die may be efficiently dissipated through a path including the high-k backside metal film and the high-k underfill material layer. In instances in which the upper package includes a dynamic random-access memory (DRAM) die, the backside metal film may provide a better thermal dissipation path between the semiconductor die and the DRAM die by connecting to the high conductivity underfill (high-k UF) material. Efficient heat dissipation from the semiconductor die may be achieved by going through the high-thermal conductivity backside metal film. Such heat dissipation may help to provide the package structure with improved performance and help the package structure to pass a reliability test.

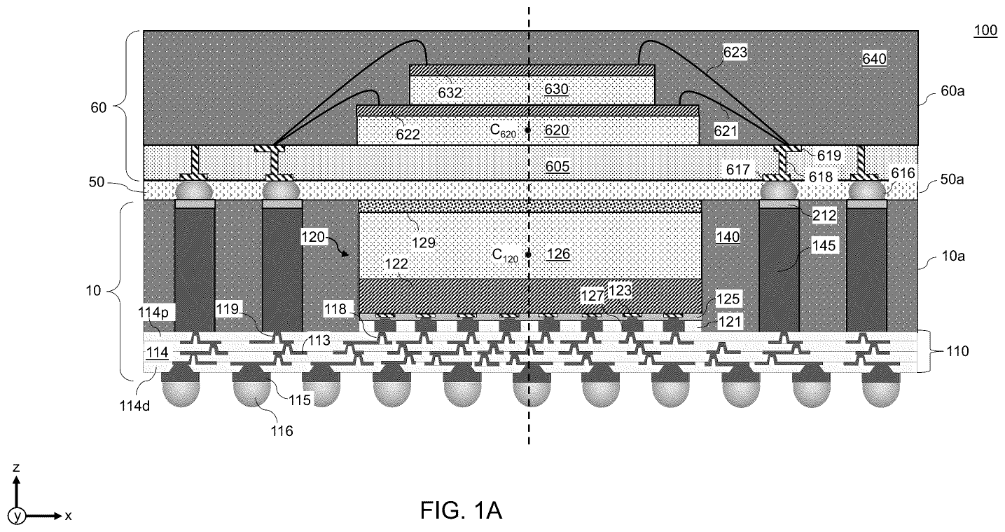

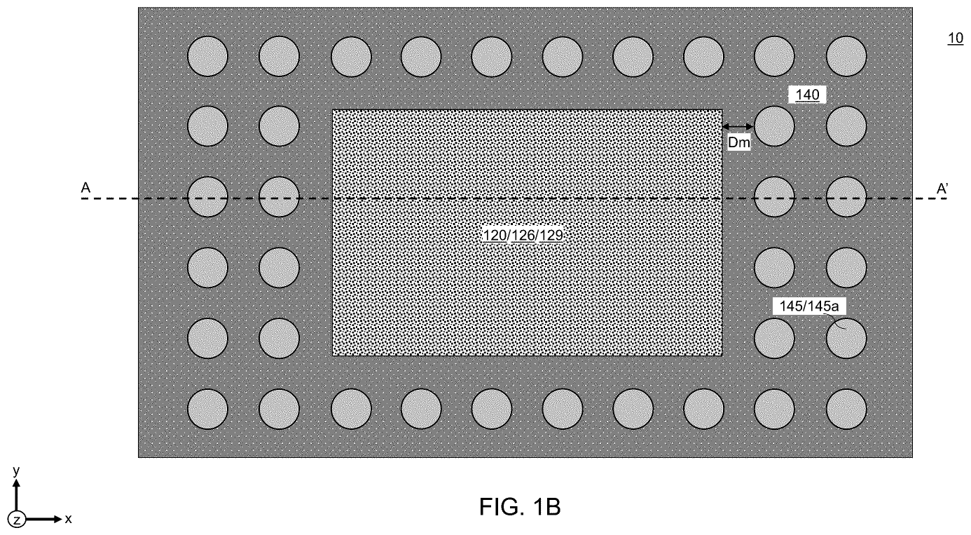

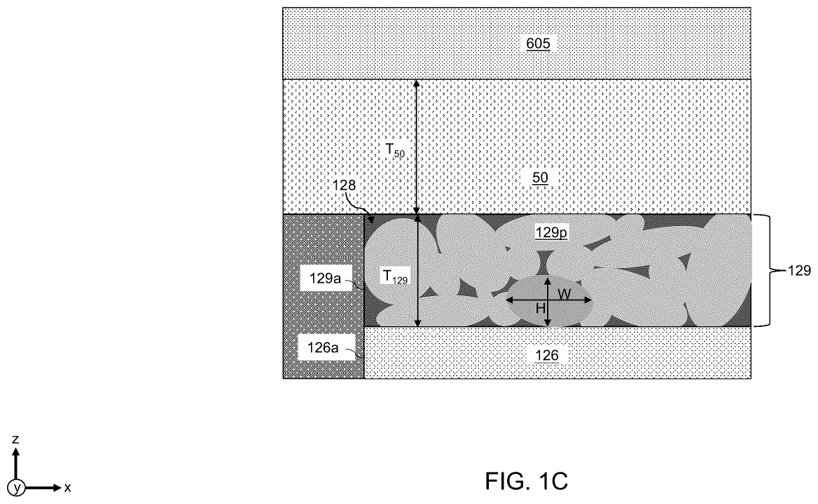

FIG. 1A is a vertical cross-sectional view of a package structure 100 according to various embodiments. FIG. 1B is a plan view (top down view) of a lower package 10 in the package structure 100 according to one or more embodiments. FIG. 1A is a cross-sectional view along the lines A-A′ in FIG. 1B. FIG. 1C is a detailed cross-sectional view of a backside metal film 129 and thermally conductive underfill layer 50 in the package structure 100 according to one or more embodiments.

It should be noted that the embodiments are not limited to any particular “package-on-package” configuration. That is, the thermal performance of other package structures besides those described in the present disclosure may be improved by the use of the backside metal film 129 and thermally conductive underfill layer 50 as described herein.

It should also be noted that the terms “proximal” and “distal” may be used at times to describe elements of the package structure 100. These terms are used with reference to a central portion (e.g., a portion including the first semiconductor die 120) of the package structure 100 in the z-direction (e.g., first vertical direction). Thus, for example, a “proximal” side of a redistribution layer may refer to a side of the redistribution layer that is nearest the central portion in the z-direction, and a “distal” side of the redistribution layer may refer to a side of the redistribution layer that is farthest away from the central portion in the z-direction.

As illustrated in FIG. 1A, the package structure 100 may include the lower package 10 and an upper package 60 mounted on the lower package 10. The lower package 10 may include a first semiconductor die 120 including a metal film 129. An underfill layer 50 may be formed between the lower package 10 and the upper package 60 and may contact the metal film 129. The backside metal film 129 and the thermally conductive underfill layer 50 may form an effective thermal dissipation path between the first semiconductor die 120 and the upper package 60.

In at least one embodiment, the frontside RDL structure 110 may include a plurality of polymer layers 114 and a plurality of redistribution layers 113 stacked alternately. The number of polymer layers 114 and/or the number of redistribution layers 113 in the frontside RDL structure 110 is not limited by the disclosure. For example, in FIGS. 1A, 3H-3M, 5, and 6, the RDL is illustrated with four polymer layers having redistribution layers formed therein. However, more or fewer polymer layers 114 and a plurality of redistribution layers 113 may be used.

In at least one embodiment, the polymer layers 114 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 113 may include conductive materials. The conductive materials may include metal such as copper, aluminum, nickel, titanium, a combination thereof or other suitable metals. The redistribution layers 113 may include metallic connection structures (e.g., metallic structures that provide electrical connection between nodes in the frontside RDL structure 110).

The redistribution layers 113 may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 113 may include copper, nickel, or copper and nickel. Other suitable metallic fill materials are within the contemplated scope of disclosure. The thickness of the metallic fill material that is deposited for each of the redistribution layers 113 may be in a range from 2 microns to 40 microns, such as from 4 microns to 10 microns, although lesser or greater thicknesses may also be used.

In at least one embodiment, the redistribution layers 113 may include a plurality of traces (lines) and a plurality of vias connecting the plurality traces to each other. The traces may be respectively located on the polymer layers 114 and may extend in the x-direction (e.g., first horizontal direction) and y-direction (e.g., second horizontal direction) on the top surface of the polymer layers 114.

In some embodiments, the polymer layers 114 in the frontside RDL structure 110 may include a distal polymer layer 114d. The distal polymer layer 114d may include an under-bump metallurgy (UBM) layer 115. The UBM layer 115 may include a metal such as copper, aluminum, nickel, titanium, a combination thereof or other suitable metals. A portion of the UBM layer 115 may be disposed on an underside of the distal polymer layer 114d and serve as a joint pad. A solder ball 116 may be disposed on the UBM layer 115 and used to mount the package structure 100 onto a substrate such as a printed circuit board (PCB). The solder ball 116 may include a standard solder material (e.g., SAC304 or SAC405). The solder material may include a lead-free solder material. The solder material may include tin and one or more other elements such as silver, indium, antimony, bismuth, zinc, etc. Other suitable solder materials are within the contemplated scope of disclosure. The UBM layer 115 may alternatively include a microbump or metal pillar (e.g., copper pillar).

The polymer layers 114 in the frontside RDL structure 110 may also include a proximal polymer layer 114p. The proximal polymer layer 114p may include one or more vias 118 that may serve as RDL bonding pads for connecting the first semiconductor die 120 to the frontside RDL structure 110. The proximal polymer layer 114p may also include one or more vias 119 that may serve as frontside bonding pads for connecting one or more through vias (TVs) 145 to the frontside RDL structure 110. The vias 119 may have a size (e.g., diameter, width in the x-direction, etc.) that is greater than a size of the vias 118. The vias 118 and vias 119 may be formed concurrently with the redistribution layers 113, and may include a metal such as copper, aluminum, nickel, titanium, a combination thereof or other suitable metals.

The first semiconductor die 120 may be attached (e.g., mounted) on the proximal polymer layer 114p of the frontside RDL structure 110. The first semiconductor die 120 may include, for example, a semiconductor chip or chiplet for a high performance computing (HPC) application, an artificial intelligence (AI) application, and a 5G cellular network application. In at least one embodiment, the first semiconductor die 120 may include a logic die (e.g., mobile application processor, microcontroller, etc.), or a memory die (e.g., dynamic random access memory (DRAM) die, a Wide I/O die, a M-RAM die, a R-RAM die, a NAND die, static random access memory (SRAM), etc.). In at least one embodiment, the first semiconductor die 120 may include a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a memory cube (e.g., HBM, HMC, etc.), a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

The first semiconductor die 120 may include, for example, an active region 122 on a frontside of the first semiconductor die 120, and a semiconductor layer 126 (e.g., bulk silicon region) on the active region 122. The active region 122 may include a front end of line (FEOL) region including electronic circuitry including various electronic devices (e.g., transistors, resistors, etc.). In particular, the FEOL region may include one or more logic circuits including logic devices (e.g., logic gates) and/or one or more memory circuits including memory devices (e.g., volatile memory (VM) devices and/or non-volatile memory (NVM) devices).

The active region 122 may also include a back end of line (BEOL) region on FEOL region. The BEOL region may include interlayer dielectric having a plurality of dielectric layers. The dielectric layers may include, for example, SiO₂, a dielectric polymer or other suitable dielectric material. The interlayer dielectric may include one or more metal interconnect structures formed therein. The metal interconnect structures may include metal traces and metal vias formed in the dielectric layers and provide an electrical connection to the electronic circuitry in the FEOL region.

The first semiconductor die 120 may also include one or more semiconductor die contact pads 123 on a surface of the active region 122. The semiconductor die contact pads 123 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The first semiconductor die 120 may also include a semiconductor die passivation layer 125 on the surface of the semiconductor die active region 122. In particular, the semiconductor die passivation layer 125 may at least partially cover the semiconductor die contact pads 123. The semiconductor die passivation layer 125 may include silicon oxide, silicon nitride, low-k dielectric materials such as carbon-doped oxides, extremely low-k dielectric materials such as porous carbon doped silicon dioxide, a combination thereof or other suitable material. A surface of the semiconductor die contact pads 123 may be exposed through openings in the passivation layer 125.

The package structure 100 may also include a dielectric layer 121 on the semiconductor die passivation layer 125. The dielectric layer 121 may include a dielectric polymer, silicon oxide, or other suitable dielectric materials. Semiconductor die bonding pads 127 may be formed in the dielectric layer 121 and contact the exposed surface of the semiconductor die contact pads 123 through the openings in the passivation layer 125. The semiconductor die bonding pads 127 may have one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. The first semiconductor die 120 may be connected to the frontside RDL structure 110 by connecting the semiconductor die bonding pads 127 to the vias 118 (e.g., RDL bonding pads) in the proximal polymer layer 114p.

The first semiconductor die 120 may also include a backside metal film 129 on a backside of the first semiconductor die 120. The backside metal film 129 may be formed on a surface of the semiconductor layer 126. The backside metal film 129 may have a good adhesion to a semiconductor material (e.g., silicon) in the semiconductor layer 126. In contrast to the die attach film, the backside metal film 129 may not protrude from a sidewall of the semiconductor layer 126.

The backside metal film 129 may include a high thermal conductivity (e.g., k>20 W/m*k) metal film. This may allow the backside metal film 129 to effectively dissipate heat generated by the first semiconductor die 120. The backside metal film 129 may be formed of one or more layers. The backside metal film 129 may have a high mechanical strength and may be ductile and malleable so that it tolerates bending and stretching without significant loss of integrity. The backside metal film 129 may also be chemically stable and substantially corrosion resistant. The backside metal film 129 may also include a rough upper surface with a high surface area which may enhance the ability of the backside metal film 129 to dissipate heat.

The backside metal film 129 (e.g., high thermal conductivity backside metal film) may include, for example, a sintered metal film. The sintered metal film may include sintered metal particles (e.g., metal powder, metal flakes, etc.). The sintered metal particles may include, for example, copper, silver, aluminum or gold. Other suitable metals may be used for the sintered metal particles.

The sintered metal film may be formed by compacting the metal particles into a solid metal film by pressure and/or heat without melting the metal particles to the point of liquefaction. The pressure and/or heat may fuse the metal particles together to form a solid metal film. The metal particles may have a controlled particle size and distribution. This may help to ensure uniformity and consistency in the sintered metal film. The sintering process may enhance the strength, electrical conductivity and thermal conductivity of the metal particles. The high temperature of the sintering process may also induce grain growth in the metal powder particles which may change the microstructure and mechanical properties of the sintered metal film. The sintering temperature, duration, and the initial particle size of the metal powder may be controlled to achieve specific pore sizes and distribution within the sintered metal film.

In at least one embodiment, the backside metal film 129 may include a high-k thermally conductive die attach film with a metal filler. The die attach film, also known as a die attach adhesive or die attach material, may include, for example, one or more layers of an epoxy resin or polyimide. The die attach film may be electrically insulating, thermally conductive and have good adhesion properties. The die attach film may also be thermally and chemically stable. The metal filler may include, for example, metal particles including one or more of stainless steel, nickel, copper, bronze, titanium, tungsten, etc. Other suitable materials for the backside metal film 129 are within the contemplated scope of disclosure.

As further illustrated in FIG. 1A, one or more through-vias (TVs) 145 may be located on the frontside RDL structure 110. The through-vias 145 may be connected to the vias 119 (e.g., RDL bonding pads) in the proximal polymer layer 114p. The through-vias 145 may have a columnar or cylindrical shape (e.g., circular cylinder shape). The through-vias 145 may have a diameter (e.g., width) in the x-direction that is greater than a width of the vias 119. The through-vias 145 may include a seed layer 212 at an end of the through-vias 145. The seed layer 212 may include, for example, copper or one or more other suitable metals. The seed layer 212 may have a height in the z-direction that is substantially the same as a height of the backside metal film 129 of the first semiconductor die 120. That is, a surface of the seed layer 212 may be substantially coplanar with a surface of the backside metal film 129. The through-vias 145 may have one or more layers and may include metals, metal alloys, and/or other metal-containing compounds (e.g., Cu, Al, Mo, Co, Ru, W, TiN, TaN, WN, etc.). Other suitable metal materials for the through-vias 145 are within the contemplated scope of disclosure.

The package structure 100 may also include a lower encapsulation layer 140 on the frontside RDL structure 110. The lower encapsulation layer 140 may laterally (e.g., in the x-direction and y-direction) encapsulate the first semiconductor die 120 and the through-vias 145. In at least one embodiment, the dielectric layer 121 may be omitted in which case the lower encapsulation layer 140 may also be located on and around the semiconductor die bonding pads 127 between the first semiconductor die 120 and the frontside RDL structure 110. A surface of the lower encapsulation layer 140 may be substantially coplanar with a surface of the seed layer 212 and a surface of the backside metal film 129. In some embodiments, the lower encapsulation layer 140 may include a molding compound, a molding underfill, a resin (such as an epoxy resin), or a combination thereof, or other suitable encapsulant materials.

As further illustrated in FIG. 1A, the upper package 60 may include a sidewall 60a substantially aligned with a sidewall 10a of the lower package 10. The upper package 60 may include a package substrate 605. The package substrate 605 may include a core substrate or core less substrate. The package substrate 605 may include one or more dielectric layers stacked in a thickness direction of the package substrate 605. In at least one embodiment, the package substrate 605 may include a build-up film substrate such as an Ajinomoto build-up film (ABF) substrate. In at least one embodiment, the package substrate includes one or more layers of epoxy resin such as a bismaleimide triazine epoxy (BT epoxy), and dielectric polymer material such as polyimide (PI), benzocyclo-butene (BCB), or polybenzobisoxazole (PBO). Other suitable dielectric materials for the package substrate 605 are within the contemplated scope of disclosure.

The package substrate 605 may include bottom contact pads 617 on a bottom surface of the package substrate 605. The package substrate may include upper contact pads 619 on an upper surface of the package substrate 605. The upper contact pads 619 may be electrically connected to the bottom contact pads 617 through one or more interconnect structures 618 (e.g., metal traces and metal vias) in the package substrate 605.

The package structure 100 may also include a plurality of solder balls 616 for attaching the upper package 60 to the lower package 10. The solder balls 616 may be located on the seed layer 212 in the lower package 10. The bottom contact pads 618 in the upper package may contact the solder balls 616 on the seed layer 212. The upper package 60 may be electrically coupled to the lower package 10 (e.g., electrically coupled to the frontside RDL structure 110) through the solder balls 616.

The upper package 60 may also include a first upper semiconductor die 620 (e.g., second semiconductor die) mounted on the package substrate 605 (e.g., by hybrid bonding, die attach film, etc.). A centerpoint C₆₂₀ (in the x-y plane) of the first upper semiconductor die 620 may be substantially aligned in the z-direction with a centerpoint C₁₂₀ (in the x-y plane) of the first semiconductor die 120 in the lower package 10. The first upper semiconductor die 620 may include an active region 622 connected to the upper contact pads 619 through one or more wires 621. The upper package 60 may also include a second upper semiconductor die 630 (e.g., third semiconductor die) mounted on the first upper semiconductor die 620 (e.g., by hybrid bonding, die attach film, etc.).

The second upper semiconductor die 630 may have a width in the x-direction that is less than a width in the x-direction of the first upper semiconductor die 620. The second upper semiconductor die 630 may include an active region 632 connected to the upper contact pads 619 through one or more wires 623. Each of the first upper semiconductor die 620 and the second upper semiconductor die 630 may be similar in design and/or function to the first semiconductor die 120 in the lower package 10 as described above. In at least one embodiment, each of the first upper semiconductor die 620 and the second upper semiconductor die 630 may include a dynamic random-access memory (DRAM) die.

The upper package 60 may also include an upper encapsulation layer 640 similar to the lower encapsulation layer 140 in the package structure 100. The upper encapsulation layer 640 may be formed on the package substrate 605 and may substantially encapsulate the first upper semiconductor die 620, the second upper semiconductor die 630, the wires 621 and the wires 623.

As further illustrated in FIG. 1A, the package structure 100 may also include a thermally conductive underfill layer 50 between the upper package 60 and the lower package 10. A sidewall 50a of the thermally conductive underfill layer 50 may be substantially aligned with the sidewall 60a of the upper package 60 and the sidewall 10a of the lower package 10. The thermally conductive underfill layer 50 may be formed around the solder balls 616 and substantially fill the gap (e.g., space) between the bottom surface of the package substrate 605 in the upper package 60 and the upper surfaces of the lower encapsulation layer 140, seed layer 212 and backside metal film 129 in the lower package 10. The thermally conductive underfill layer 50 may enhance heat dissipation and thermal performance by improving the thermal conductivity (e.g., enhance heat transfer) between the first semiconductor die 120 and the package substrate 605.

The thermally conductive underfill layer 50 may help to fix the upper package 60 to the lower package 10. The thermally conductive underfill layer 50 may have a low viscosity (e.g., less than about 5,000 cP at 10 rpm), and may be formed of an epoxy-based polymeric material. In at least one embodiment, the thermally conductive underfill layer 50 may include a capillary underfill including a mixture of epoxy and silica. In at least one embodiment, the thermally conductive underfill layer 50 may include a low-viscosity suspension of silica in prepolymer.

The thermally conductive underfill layer 50 may have a thermal conductivity greater than 20 W/m·K. The thermally conductive underfill layer 50 may include, for example, a filled polymer underfill. The filled polymer underfill may include thermally conductive fillers such as ceramic particles, metal particles, or carbon fibers suspended within a polymer material (e.g., polymer matrix). It should be noted that an underfill material may be modified to be a high-k underfill material by adding a higher percentage of filler (e.g., metal filler) or changing the high-k thermally conductive fillers in the underfill material.

Referring to FIG. 1B, the first semiconductor die 120 may be located in a central region of the lower package 10. An outer edge of the backside metal film 129 may be substantially aligned with an outer edge of the semiconductor layer 126 around an entire periphery of the first semiconductor die 120. In at least one embodiment, the backside metal film 129 may have a width in the x-direction less than or equal to a width in the x-direction of the semiconductor layer 126, and a length in the y-direction less than or equal to a length in the y-direction of the semiconductor layer 126.

The lower encapsulation layer 140 may contact the outer edge of the backside metal film 129 and the semiconductor layer 126 around the entire periphery of the first semiconductor die 120. The through-vias 145 may be formed in the lower encapsulation layer 140 around the entire periphery of the first semiconductor die 120. The through-vias 145 may be formed in two or more rows extending in the x-direction or two or more columns extending in the y-direction. A spacing between the through-vias 145 may be substantially uniform around the entire periphery of the first semiconductor device 120.

A minimum distance Dm between the through-vias 145 and the backside metal film 129 (e.g., the first semiconductor die 120) may be substantially uniform around the entire periphery of the first semiconductor die 120. The minimum distance Dm may be 100 μm or greater.

Referring to FIG. 1C, the backside metal film 129 may have a thickness T₁₂₉ less than or equal to 100 μm. In at least one embodiment, the backside metal film 129 may have a thickness T₁₂₉ less than or equal to 20 μm. In at least one embodiment, the thickness T₁₂₉ of the backside metal film 129 may constitute at least 10% of a combined thickness of the active region 122, the semiconductor layer 126 and the backside metal film 129. In at least one embodiment, the thickness T₁₂₉ of the backside metal film 129 may be at least 30% of the thickness T₅₀ of the thermally conductive underfill layer 50.

The backside metal film 129 may include a sintered metal film including a plurality of sintered metal particles 129p. The sintered metal film may also include pores 128 (e.g., voids) between the sintered metal particles 129p. The sintered metal particles 129p (e.g., metal filler) may include random shapes such as ellipsoid, spheroid, cuboid, etc. Other suitable shapes of the sintered metal particles 129p are within the contemplated scope of disclosure.

The sintered metal particles 129p (e.g., metal filler) may include different sizes and different orientations (e.g., longitudinal directions) in the backside metal film 129. The sintered metal particles 129p may have a size (e.g., length, width, diameter) less than 100 μm. In at least one embodiment, the sintered metal particles 120p may have a width W in the x-direction of less than 100 μm and a height H in the y-direction of less than 100 μm.

As illustrated in FIG. 1C, a sidewall 129a of the backside metal film 129 may be substantially aligned with a sidewall 126a of the semiconductor layer 126. That is, the sidewall 129a of the backside metal film 129 may not protrude from the sidewall 126a of the semiconductor layer 126. In at least one embodiment, a width of the backside metal film 129 may be slightly less than a width of the semiconductor layer 126. In such an embodiment, the sidewall 129a of the backside metal film 129 may not be aligned with the sidewall 126a of the semiconductor layer 126 but may be just inside the sidewall 126a of the semiconductor layer 126 in the x-direction and the y-direction. Further, a distance between the sidewall 129a of the backside metal film 129 and the sidewall 126a of the semiconductor layer 126 may be less than 10 μm.

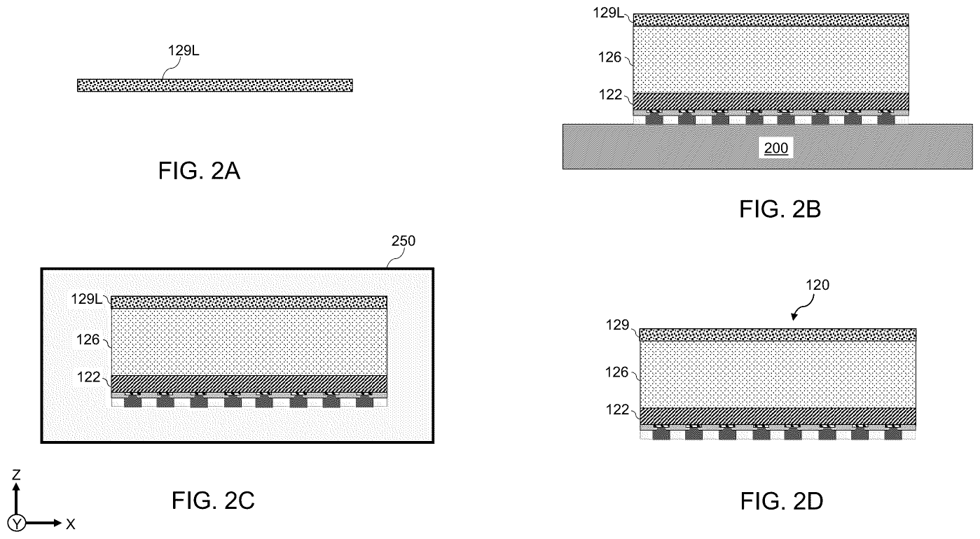

FIGS. 2A-2D illustrate various method steps in forming the first semiconductor die 120 according to one or more embodiments. In particular, FIG. 2A illustrates a sintered metal layer 129L according to one or more embodiments. The sintered metal layer 129L may be fabricated by using heat (e.g., or heat and pressure) to sinter or fuse metal particles (e.g., metal powder, metal flakes, etc.) together, creating a continuous and conductive metal layer.

In at least one embodiment, a method of forming the sintered metal layer 129L may include cleaning a substrate surface on which the sintered metal layer 129L is to be formed. The cleaning of the substrate surface may mitigate against the contamination of the sintered metal layer 129L. The metal particles may then be deposited onto the substrate surface to create a thin layer of the metal particles. The metal particles may be deposited, for example, by screen printing, inject printing, spray coating, etc. In embodiments in which a liquid carrier is used during deposition of the metal particles, the substrate may be heated or allowed to dry to remove the carrier and leave the metal particles on the surface.

The deposited metal particles may then be sintered by heating the substrate with the deposited metal particles to a temperature below the metal's melting point but high enough for the particles to fuse together. Pressure may optionally be applied during the sintering process to facilitate particle bonding between the metal particles. After sintering, the substrate may be gradually cooled down, allowing the fused metal particles to solidify and create the sintered metal layer 129L (e.g., a cohesive metal film). The sintered metal layer 129L may then be tested to ensure that it has a thermal conductivity greater than 20 W/m·K.

At this point, the sintered metal layer 129L may undergo additional processes to enhance the sintered metal layer 129L properties, such as planarization or surface coating. In particular, the sintered metal layer 129 may undergo a planarization process to provide a uniform thickness of less than or equal to 20 μm. The sintered metal layer 129 may also undergo a roughening process (e.g., etching, abrasion, etc.) to increase its surface area and increase its heat transfer efficiency.

The sintered metal layer 129L may also be treated by one or more processes to enhance the thermal conductivity of the sintered metal layer 129L. For example, the sintered metal layer 129L may be annealed to reduce defects, dislocations, and grain boundaries within the film, improving its crystal structure and thermal conductivity. A surface of the sintered metal layer 129L may also be coated with a thin layer of a high thermally conductive material (e.g., boron nitride) to enhance the thermal conductivity of the sintered metal layer 129L.

FIG. 2B illustrates the sintered metal layer 129L applied to a surface of the semiconductor layer 126 according to one or more embodiments. As illustrated in FIG. 2B, the intermediate structure may be placed on a heated stage 200. The heated stage may be heated to a temperature in a range from 50° C. to 100° C. The sintered metal layer 129L may then be applied to an upper surface of the semiconductor layer 126 by a film lamination process using a roller.

FIG. 2C illustrates the curing of the sintered metal layer 129L in an oven 250 according to one or more embodiments. In at least one embodiment, the sintered metal layer 129L (the sintered metal layer 129L when attached to the semiconductor layer may be referred to as backside metal film 129) may be cured in the oven 250 at a temperature in a range from 120° C. to 180° C. for a duration in a range of 1.5 hours to 2.5 hours.

FIG. 2D illustrates the first semiconductor die 120 including the backside metal film 129 according to one or more embodiments. After the sintered metal film 129L has been adequately cured in the oven, the semiconductor die 120 (including semiconductor layer 126, active region 122, and backside metal film 129) may be removed from the oven and allowed to cool at room temperature. At this point, the backside metal film 129 may be securely attached (e.g., bonded, fused, etc.) to the surface of the semiconductor layer 126 and the formation of the first semiconductor die 120 may be complete.

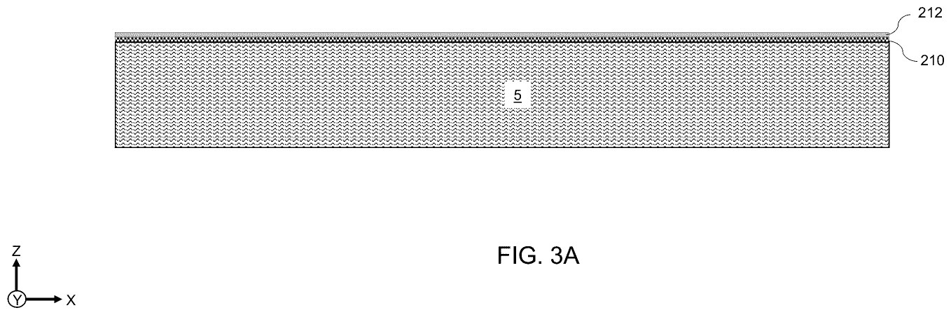

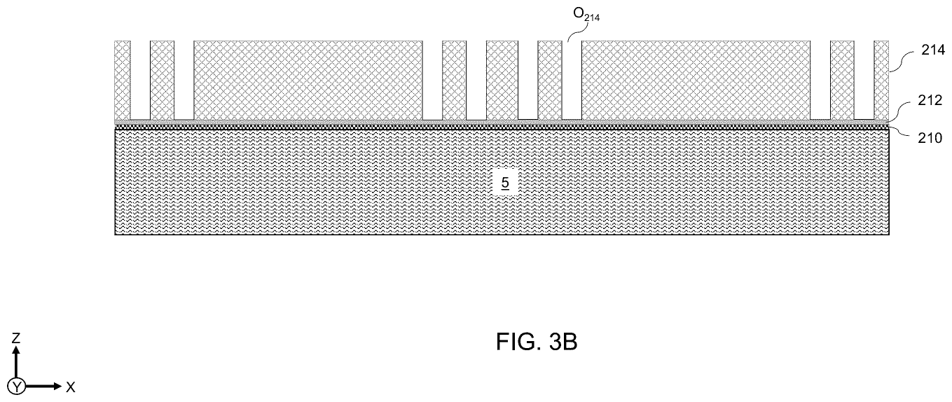

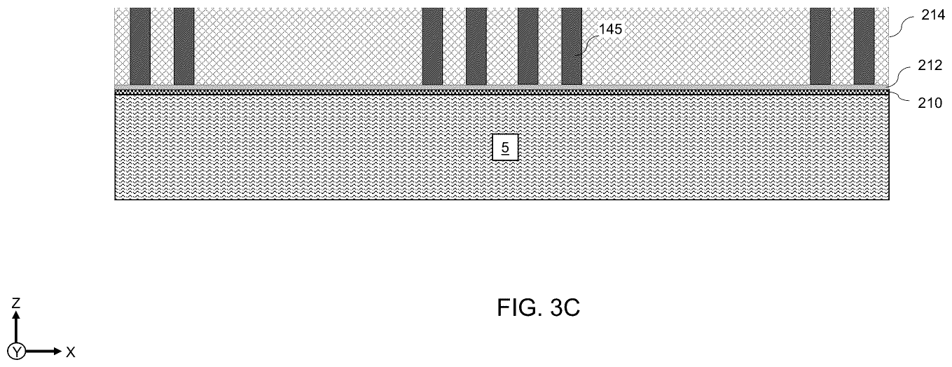

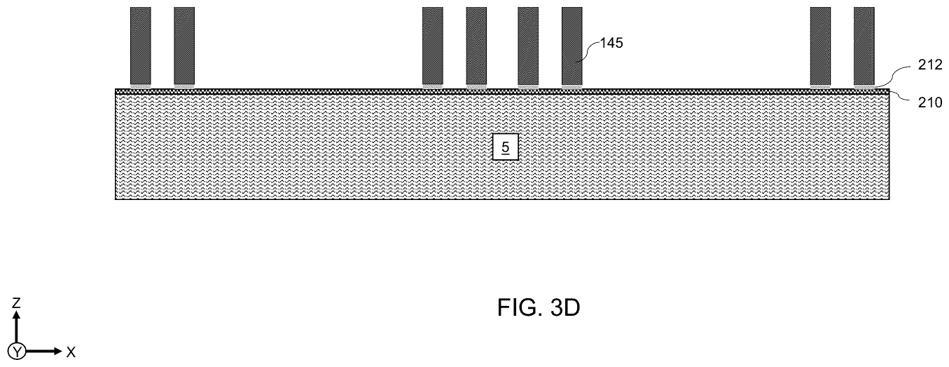

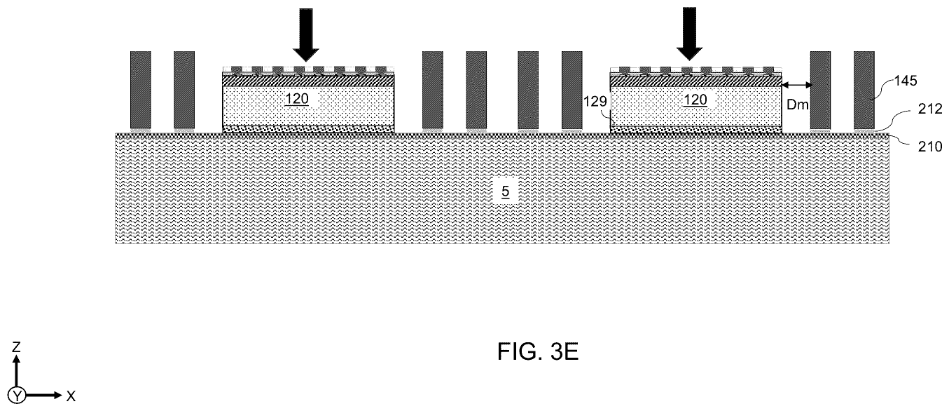

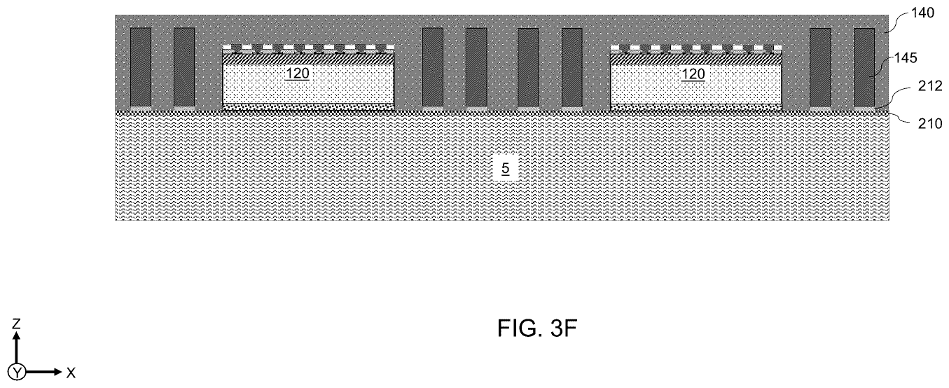

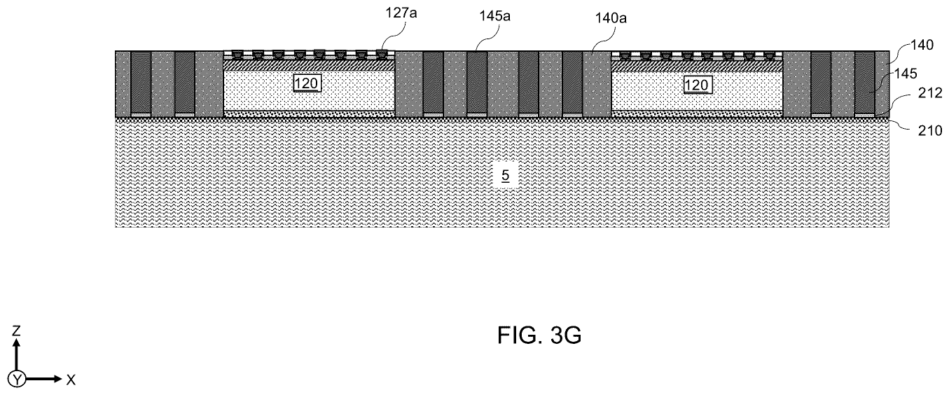

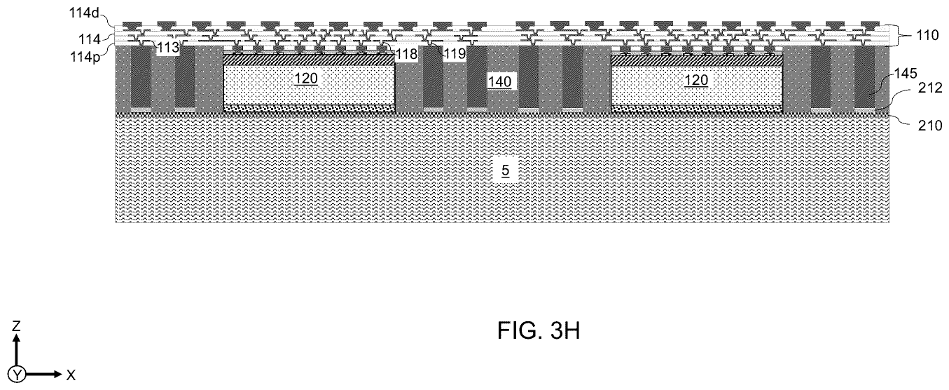

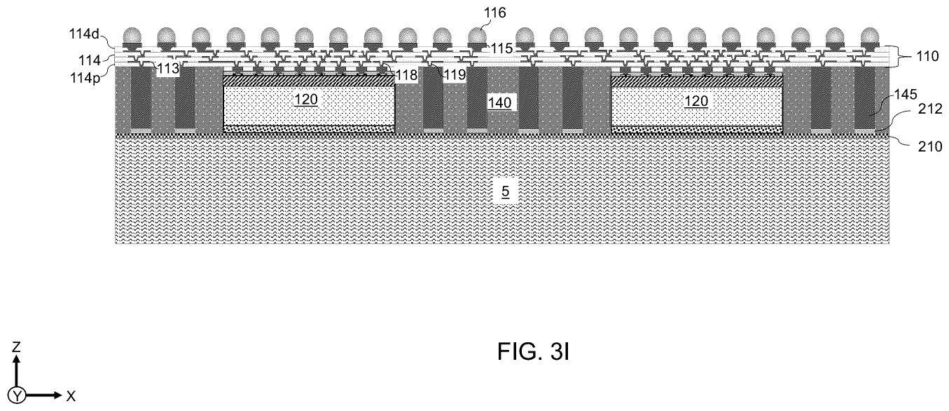

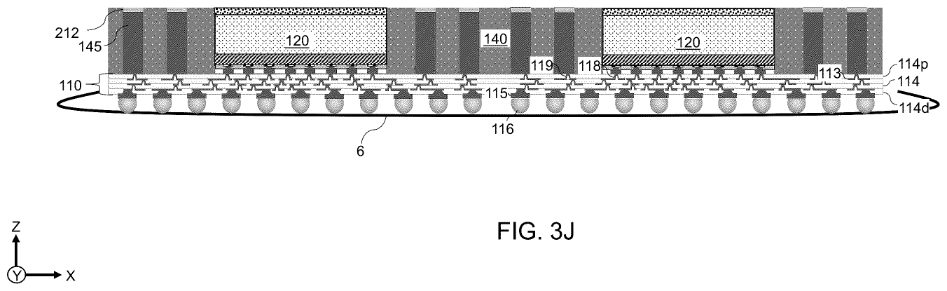

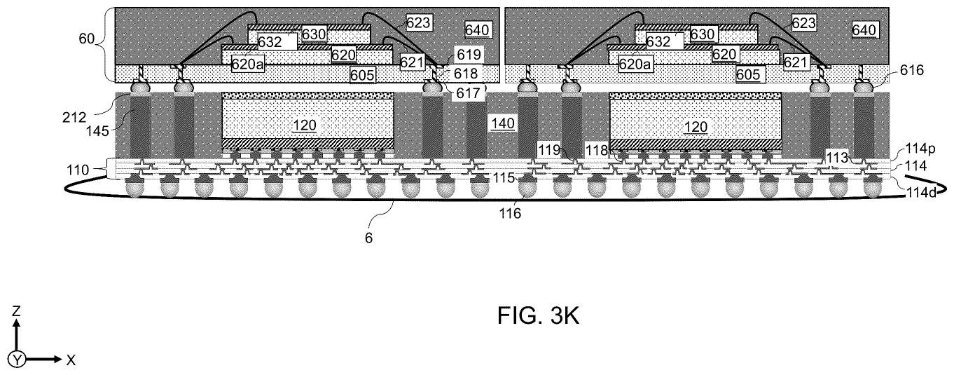

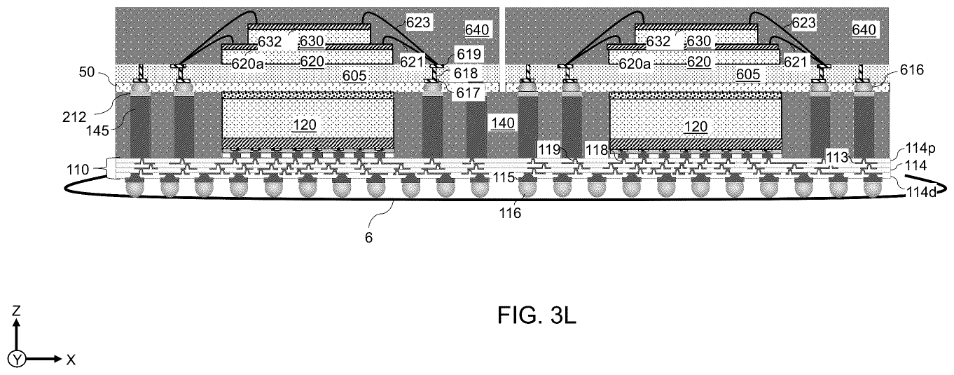

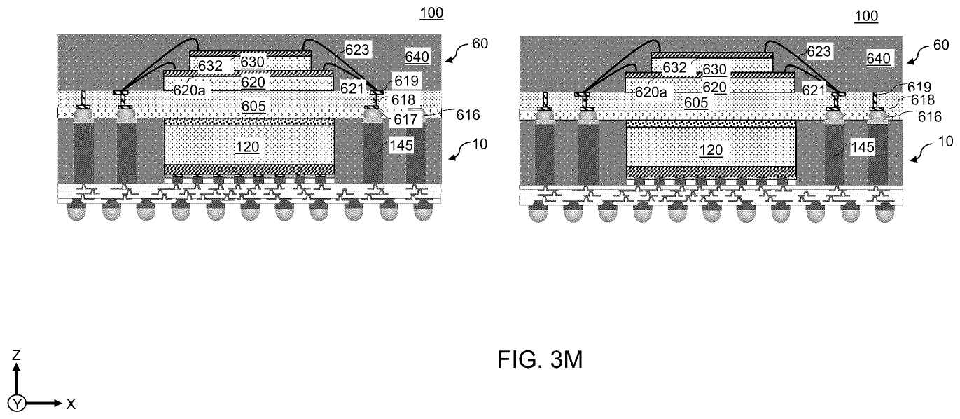

FIGS. 3A-3M are views of various intermediate structures in a method of forming the package structure 100 according to one or more embodiments. In particular, FIG. 3A is a vertical cross-sectional view of an intermediate structure including a seed layer 212 on an adhesive layer 210 according to one or more embodiments.

As illustrated in FIG. 3A, an adhesive layer 210 may be formed on an upper surface of a carrier substrate 5. The carrier substrate 5 may include a semiconductor wafer (e.g., circular wafer or a rectangular wafer) or glass substrate. The lateral dimensions (such as the diameter of a circular wafer or a side of a rectangular wafer) of the carrier substrate 5 may be in a range from 100 mm to 500 mm, such as from 200 mm to 400 mm, although lesser and greater lateral dimensions may also be used. The carrier substrate 5 may be transparent or opaque. The thickness of the carrier substrate 5 may be sufficient to provide mechanical support to the package structure 100. For example, the thickness of the carrier substrate 5 may be in a range from 60 microns to 1 mm, although lesser and greater thicknesses may also be used.

The adhesive layer 210 may include a light-to-heat conversion (LTHC) layer or may include a thermally decomposing adhesive material. In at least one embodiment, the adhesive layer 210 may cover an entirety of the carrier substrate 5. The LTHC layer may include a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

A seed layer 212 (e.g., metallic seed layer, copper seed layer, etc.) may then be formed on the adhesive layer 210. In at least one embodiment, the seed layer 212 may cover an entirety of the adhesive layer 210. The seed layer 212 may be formed, for example, by depositing the seed layer 212 in a deposition process such as chemical vapor deposition (CVD), plasma-enhanced chemical vapor deposition (PECVD), physical vapor deposition (PVD), spin coating, lamination or other suitable deposition technique. The seed layer 212 may include, for example, one or more layers and may include one or more metals, metal alloys, and/or other metal-containing compounds (e.g., Cu, Al, Mo, Co, Ru, W, TiN, TaN, WN, etc.). Other suitable metal materials are within the contemplated scope of disclosure.

FIG. 3B is a vertical cross-sectional view of an intermediate structure including a photoresist layer 214 according to one or more embodiments. The photoresist layer 214 may be formed to have a thickness greater than a thickness of the first semiconductor die 120. The photoresist layer 214 may then be patterned to form a pattern of openings O₂₁₄ through the photoresist layer 214. The bottom of the openings O₂₁₄ may be constituted by an upper surface of the seed layer 212. The photoresist layer 214 may be patterned, for example, by forming a mask layer (not shown) on an upper surface of the photoresist layer 214, and patterning the mask layer to have a pattern corresponding to the desired pattern in the photoresist layer 214. The photoresist layer 214 may then be patterned through the openings in the mask layer by an etching process (e.g., wet etching, dry etching, etc.) to form the openings O₂₁₄. The etching process may be performed until the upper surface of the seed layer 212 is exposed. The mask layer may then be removed to expose the upper surface of the photoresist layer 214.

FIG. 3C is a vertical cross-sectional view of an intermediate structure including the through-vias 145 according to one or more embodiments. As illustrated in FIG. 3C, the through-vias 145 may be formed in the openings O₂₁₄ in the photoresist layer 214. The through-vias 145 may formed by electroplating a metallic fill material (such as copper) in the openings O₂₁₄ using the seed layer 212 which is exposed at the bottom of the openings O₂₁₄. The metal material for electroplating may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

After the openings O₂₁₄ are filled with the metallic fill material, upper surfaces of the metallic fill material and the photoresist layer 214 may be planarized, for example, by chemical mechanical polishing (CMP) or another suitable planarization technique. After planarization, the upper surface of the metallic fill material (e.g., an upper surface of the through-vias 145) may be substantially coplanar with an upper surface of the photoresist layer 214.

FIG. 3D is a vertical cross-sectional view of an intermediate structure including the through-vias 145 according to one or more embodiments. After the upper surfaces of the metallic fill material constituting the through-vias 145 and photoresist layer 214 are planarized, the photoresist layer 214 may then be removed, for example, by etching (e.g., wet etching, dry etching, etc.). The seed layer 212 (e.g., underbump metallization (UBM) layer) may also be etched (e.g., wet etching, dry etching, etc.) to expose an upper surface of the adhesive layer 210 between the through-via 145.

The seed layer 212 may be etched concurrently in the same etching step with the photoresist layer 214, or in a separate step after the etching of the photoresist layer 214. As illustrated in FIG. 3D, after the etching of the seed layer 212, portions of the seed layer 212 may remain unetched beneath the through-vias 145, respectively.

FIG. 3E is a vertical cross-sectional view of an intermediate structure including the first semiconductor die 120 according to one or more embodiments. The first semiconductor die 120 (including the backside metal film 129) may be inverted so that the backside metal film 129 faces the adhesive layer 210 and then placed on the adhesive layer 210. An entirety of the upper surface of the backside metal film 129 may contact the upper surface of the adhesive layer 210. In at least one embodiment, the first semiconductor die 120 may be placed on the upper surface of the adhesive layer 210 by a pick-and-place (PnP) process (e.g., a robotic PnP process). The first semiconductor die 120 may be placed on the adhesive layer 210 so that a minimum distance Dm (e.g., 100 μm or greater) is maintained between the backside metal film 129 and an adjacent through-via 145 around the periphery of the first semiconductor die 120. A pressing force (indicated by the directional arrows in FIG. 3E) may then be applied to the first semiconductor die 120 to press the backside metal film 129 onto the surface of the adhesive layer 210. The intermediate structure may then be heated (e.g., in an oven) to securely fix the backside metal film 129 to the surface of the adhesive layer 210. As illustrated in FIG. 3E, height of the through-vias 145 may be greater than a height of first semiconductor die 120.

FIG. 3F is a vertical cross-sectional view of an intermediate structure including the lower encapsulation layer 140 according to one or more embodiments. The lower encapsulation layer 140 may be formed by a sequence of an over-molding process and a planarization process. In particular, the lower encapsulation layer 140 (e.g., an epoxy molding compound (EMC) may be formed over the adhesive layer 210 to fill gaps between the first semiconductor die 120 and the through-vias 145 and encapsulate the first semiconductor die 120 and the through-vias 145. The lower encapsulation layer 140 may be formed to have a height greater than a height of the through-vias 145. The lower encapsulation layer 140 may be formed, for example, by a deposition process such as CVD, PECVD, PVD, spin coating, lamination or other suitable deposition technique.

FIG. 3G is a vertical cross-sectional view of an intermediate structure including the lower encapsulation layer 140 after performing the planarization process, according to one or more embodiments. As illustrated in FIG. 3G, the planarization process may be performed on a surface 140a of the lower encapsulation layer 140 until an upper surface 145a of the through-vias 145 and an upper surface 127a of the semiconductor die bonding pads 127 are exposed. That is, the planarization process may be performed until the surface 140a of the lower encapsulation layer 140 is substantially coplanar with the upper surface 145a of the through-vias 145 and the upper surface 127a of the semiconductor die bonding pads 127. The planarization process may include, for example, a mechanical grinding process and/or a chemical mechanical polishing (CMP) process.

FIG. 3H is a vertical cross-sectional view of an intermediate structure including the frontside RDL structure 110, according to one or more embodiments. The polymer layers 114 and redistribution layers 113 may be alternatingly formed in a series of process steps. In particular, the proximal polymer layer 114p may be formed on the lower encapsulation layer 140. The proximal polymer layer 114p may be formed, for example, by a deposition process such as CVD, PECVD, PVD, spin coating, lamination or other suitable deposition technique.

Openings may be formed in the proximal polymer layer 114p (e.g., by etching in a photolithographic process). A redistribution layer 113 may then be formed (e.g., by an electroplating process) in the openings and on the proximal polymer layer 114p. In this manner, the vias 118 (e.g., RDL bonding pads) may be formed so as to contact the semiconductor die bonding pads 127, and the vias 119 (e.g., frontside bonding pads) may be formed so as to contact the through-vias 145. The remaining polymer layers 114 and redistribution layers 113 of the frontside RDL structure 110 may then be alternatingly formed in a similar manner. Openings may then be formed (e.g., by a photolithographic process) in the distal polymer layer 114d and the UBM layer 115 may be formed (e.g., by an electroplating process) in the openings and on the surface of the distal polymer layer 114d.

FIG. 3I is a vertical cross-sectional view of an intermediate structure including the solder balls 116, according to one or more embodiments. As illustrated in FIG. 3I, the solder balls 116 may be formed on UBM layer 115. The solder balls 116 may be formed, for example, by a suitable process such as reflow, evaporation, ball drop, screen printing, or electroplating.

FIG. 3J is a vertical cross-sectional view of an intermediate structure on a carrier tape 6, according to one or more embodiments. After the solder balls 116 are formed on the UBM layer 115, the intermediate structure may be inverted and placed on a carrier tape 6. The carrier tape 6 may include a thin, flexible strip made of plastic. The carrier tape 6 may optionally include a pattern of pockets or cavities that precisely match the arrangement of the solder balls 116 on the intermediate structure. The intermediate structure may be positioned so that each solder ball 116 sits within its corresponding pocket. A cover tape (not shown) may then be applied over the carrier tape 6, sealing the solder balls 116 within their respective pockets. The cover tape may be made of transparent plastic and securely bonded to the carrier tape 6, creating a protective barrier.

The intermediate structure may then be de-bonded from the carrier substrate 5. The intermediate structure may be de-bonded from the carrier substrate 5, for example, by decomposing (e.g., by using heat, ultraviolet (UV) light, etc.) the adhesive layer 210 that adhered the carrier substrate 5 to a surface of the intermediate structure. An LTHC cleaning step (e.g., post-laser drill clean) or other suitable cleaning process may then be performed in order to clean the surface of the intermediate structure. The cleaning process may promote the removal of the adhesive layer 210 from the surface of the intermediate structure. A pre-solder layer (not shown) may also optionally be formed on the exposed surface of the seed layer 212. The pre-solder layer may be formed, for example, by a suitable process such as reflow, evaporation, ball drop, screen printing, or electroplating. Such processes provide a significant time and cost savings over related methods that use a die attach film as such die attach films may use a dry etch process to remove the die attach film.

FIG. 3K is a vertical cross-sectional view of an intermediate structure including the upper package 60, according to one or more embodiments. The upper package 60 may be fabricated by a process in which the first upper semiconductor die 620 (e.g., second semiconductor die) is mounted on the package substrate 605. A pick-and-place machine may be used to locate the first upper semiconductor die 620 over the package substrate 605 so as to be subsequently aligned with the first semiconductor die 120. The first upper semiconductor die 620 may be attached to the package substrate 605 by a die attach film, by hybrid bonding or by other suitable bonding methods.

The second upper semiconductor die 630 (e.g., third semiconductor die) may then be mounted on the first upper semiconductor die 620. The pick-and-place machine may also be used to locate the second upper semiconductor die 630 over the first upper semiconductor die 620 and align the second upper semiconductor die 630 with the first upper semiconductor die 620. The second upper semiconductor die 630 may be attached to the first upper semiconductor die 620 by a die attach film, by hybrid bonding or by other suitable bonding methods. Ends of the wires 621 and wires 623 may then be attached (e.g., by soldering) to the active region 622 of the first upper semiconductor die 620 and to the active region 632 of the second upper semiconductor die 630, respectively. The other ends of the wires 621 and wires 623 may then be attached (e.g., by soldering) to the upper contact pads 619. The upper encapsulation layer 640 may then be formed on the package substrate 605 in a manner similar to the method of forming the lower encapsulation layer 140 describes above. Solder balls 616 may then be formed on the lower contact pads 617 in a manner similar to the method of forming the solder balls 116.

After the upper package 60 is formed, the upper package 60 may be mounted on the lower package 10. A pick-and-place machine may be used to locate the upper package 60 over the lower package 10 so as to align the solder balls 616 with the portions of seed layer 212 on the through-vias 145. The pick-and-place machine may then lower the upper package 60 onto the lower package 10, and heat and/or pressure may be applied to bond the upper package 60 to the lower package 10.

FIG. 3L is a vertical cross-sectional view of the intermediate structure including the thermally conductive underfill layer 50 according to one or more embodiments. The thermally conductive underfill layer 50 (e.g., epoxy-based polymeric material) may be dispensed (e.g., injected) onto the upper surface of the lower package 10, under the package substrate 605 and around the solder balls 616. As illustrated in FIG. 3L, the thermally conductive underfill layer 50 may be formed separately under each of the upper packages 60. The thermally conductive underfill layer 50 may alternatively be formed continuously under the entirety of the upper packages 60. The thermally conductive underfill layer 50 may then be cured, for example, in a box oven for duration in a range from 60 minutes to 120 minutes at a temperature in a range from 120° C. to 180° C. to provide the thermally conductive underfill layer 50 with a sufficient stiffness and mechanical strength.

FIG. 3M is a vertical cross-sectional view of the completed package structure 100 after dicing according to one or more embodiments. As illustrated in FIG. 3M, after the thermally conductive package underfill 50 has cured, the intermediate structure of FIG. 3L may be separated into individual units (e.g., into a plurality of package structures 100). In at least one embodiment, individual package structures 100 may be separated from adjoining package structures 100 by using a dicing saw. The package structure 100 may be diced with the dicing saw along dicing lines between adjoining package structures 100.

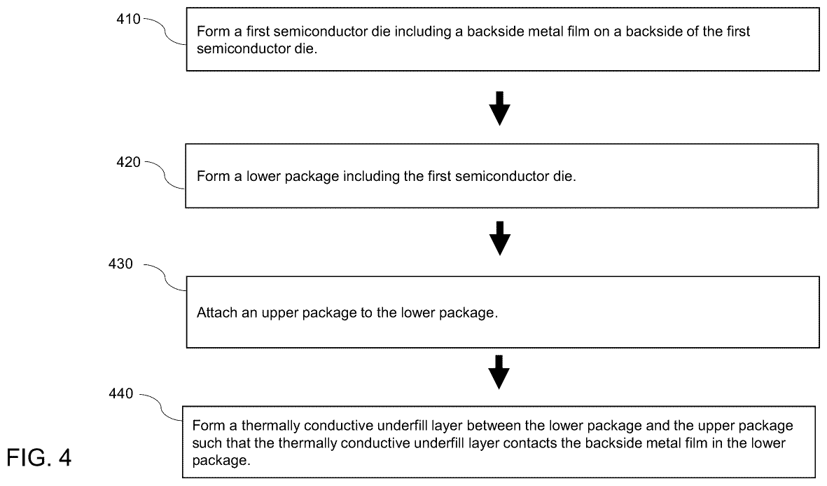

FIG. 4 is a flow chart illustrating a method of forming a package structure 100, according to one or more embodiments. Step 410 of the method may include forming a first semiconductor die including a backside metal film on a backside of the first semiconductor die. Step 420 may include forming a lower package including the first semiconductor die. Step 430 may include attaching an upper package to the lower package. Step 440 may include forming a thermally conductive underfill layer between the lower package and the upper package such that the thermally conductive underfill layer contacts the backside metal film in the lower package.

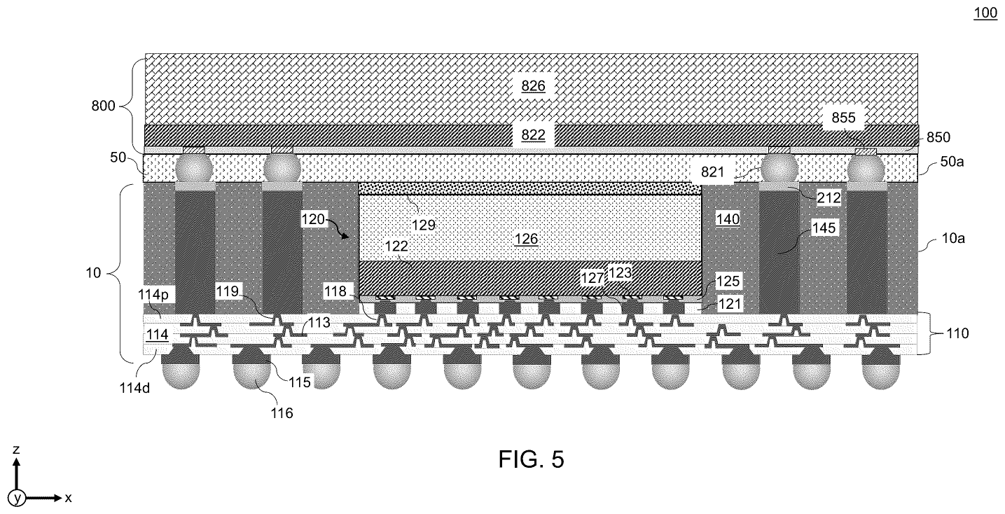

FIG. 5 is a vertical cross-sectional view of the package structure 100 having a first alternative design according to one or more embodiments. The first alternative design of the package structure 100 may be substantially similar to the original design in FIG. 1A. However, in the first alternative design, the upper package 60 may be replaced with an upper semiconductor die 800. The upper semiconductor die 800 may be substantially the same as the first semiconductor die 120. In at least one embodiment, the upper semiconductor die 800 may include a memory die such as a DRAM die.

In the first alternative design, the upper semiconductor die 800 may be flip-chip mounted on the lower package 10. The upper semiconductor die 800 may include an active region 822 on a frontside of the upper semiconductor die 800. The upper semiconductor die 800 may also include a semiconductor layer 826 (e.g., bulk silicon region) on the active region 822. The frontside of the upper semiconductor die 800 may also include a passivation layer 850 and a plurality of bonding pads 855 in the passivation layer 850. The upper semiconductor die 800 may be connected to the lower package by a plurality of C4 bumps 821 formed on the bonding pads 855, respectively, and connected to the portions of seed layer 212 on the through-vias 145, respectively. The thermally conductive underfill layer 50 may be formed on the lower package 10 and around the C4 bumps 821. The thermally conductive underfill layer 50 may completely fill the gap between the upper semiconductor die 800 and the lower package 10.

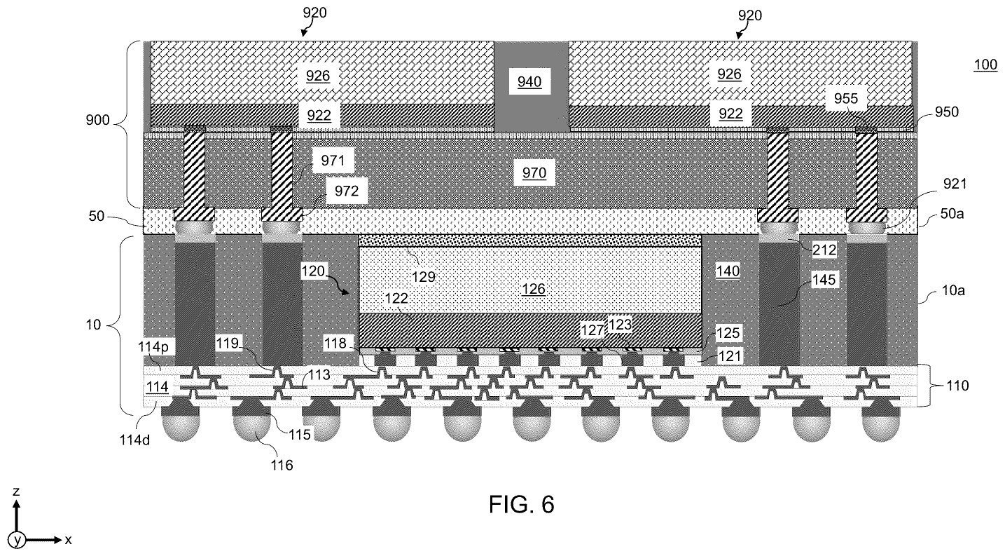

FIG. 6 is a vertical cross-sectional view of the package structure 100 having a second alternative design according to one or more embodiments. The second alternative design of the package structure 100 may also be substantially similar to the original design in FIG. 1A. However, in the second alternative design the upper package 60 may be replaced with an upper package 900. The upper package 900 may include an interposer 970 (e.g., silicon interposer) including a plurality of through silicon vias (TSVs) 971 and a plurality of bonding pads 972 connected to the TSVs 971 on a frontside of the upper package 900.

The upper package 900 may also include one or more upper dies 920 flip-chip mounted on the interposer 970, for example, by a hybrid bond. The upper dies 920 may be substantially the same as the first semiconductor die 120. The upper dies 920 may be the same or different. In at least one embodiment, one or more of the upper dies 920 may include a memory die such as a DRAM die. The upper dies 920 may be embedded in a molding material 940 that is formed on the interposer 970.

In the second alternative design, the upper dies 920 may include an active region 922 on a frontside of the upper die 920. The upper dies 920 may also include a semiconductor layer 926 (e.g., bulk silicon region) on the active region 922. The frontside of the upper die 920 may also include a passivation layer 950 and a plurality of bonding pads 955 in the passivation layer 950. The bonding pads 955 may be connected to the TSVs 971 in the interposer 970.

The upper package 900 may be connected to the lower package 10 by a plurality of C4 bumps 921 formed on the bonding pads 972, respectively, and connected to the portions of seed layer 212 on the through-vias 145, respectively. The thermally conductive underfill layer 50 may be formed on the lower package 10 and around the C4 bumps 921. The thermally conductive underfill layer 50 may completely fill the gap between the upper package 900 and the lower package 10.

Referring now to FIGS. 1A-6, a package structure 100 may include a lower package 10 including a first semiconductor die 120 including a backside metal film 129 on a backside of the first semiconductor die 120, an upper package 60, 900 attached to the lower package 10 and electrically coupled to the lower package 10, and a thermally conductive underfill layer 50 between the lower package 10 and the upper package 60, 900 and contacting the backside metal film 129.

In one embodiment, the backside metal film 129 may have a thermal conductivity greater than 20 W/m·K. In one embodiment, the backside metal film 129 may include a sintered metal film including metal particles. In one embodiment, the backside metal film 129 may have a thickness less than or equal to 20 μm. In one embodiment, the metal particles have a width in a first direction less than 100 μm, and a length in a second direction perpendicular to the first direction less and 100 μm. In one embodiment, the metal particles may include at least one of copper, silver, aluminum or gold. In one embodiment, the first semiconductor die 120 may further include a semiconductor layer 126 and the backside metal film 129 may be attached to the semiconductor layer 126. In one embodiment, a width of the backside metal film 129 in a first direction may be less than or equal to a width of the semiconductor layer 126 in the first direction, and a length of the backside metal film 129 in a second direction perpendicular to the first direction may be less than or equal to a length of the semiconductor layer 126 in the second direction. In one embodiment, the lower package 10 may further include a lower encapsulation layer 140 and the first semiconductor die 120 may be in the lower encapsulation layer 140 such that an upper surface of the backside metal film 129 may be substantially coplanar with an upper surface of the lower encapsulation layer 140. In one embodiment, the thermally conductive underfill layer 50 may include epoxy resin and metal particles dispersed in the epoxy resin. In one embodiment, the thermally conductive underfill layer 50 may have a thermal conductivity greater than 20 W/m·K. In one embodiment, the upper package 60, 900 may include a package substrate 605 and a second semiconductor die 620 attached to the package substrate 605 and electrically coupled to the lower package 10 through the package substrate 605. In one embodiment, the lower package 10 may further include a frontside redistribution layer (RDL) structure and a through via adjacent the first semiconductor die 120 on the frontside RDL structure 110, and the second semiconductor die 620 may include a dynamic random access memory (DRAM) die electrically coupled to the frontside RDL structure 110 by the through via. In one embodiment, the thermally conductive underfill layer 50 may have a thickness greater than a thickness of the backside metal film 129 and substantially fills a space between the package substrate 605 and the backside metal film 129.

Referring again to FIGS. 1A-6, a method of making a package structure 100 may include forming a first semiconductor die 120 including a backside metal film 129 on a backside of the first semiconductor die 120, forming a lower package 10 including the first semiconductor die 120, attaching an upper package 60, 900 to the lower package 10, and forming a thermally conductive underfill layer 50 between the lower package 10 and the upper package 60, 900 such that the thermally conductive underfill layer 50 contacts the backside metal film 129 in the lower package 10.

In one embodiment, the backside metal film 129 may include a sintered metal film and the forming of the backside metal film 129 may include forming a metal film material layer 129L including a plurality of metal particles on a backside surface of the first semiconductor die 120, and heating the metal film material layer 129L to form the sintered metal film. In one embodiment, the first semiconductor die 120 may further include a semiconductor layer 126 and the forming of the backside metal film 129 may include forming the backside metal film 129 on the semiconductor layer 126 such that a width of the backside metal film 129 in a first direction may be less than or equal to a width of the semiconductor layer 126 in the first direction, and a length of the backside metal film 129 in a second direction perpendicular to the first direction may be less than or equal to a length of the semiconductor layer 126 in the second direction. In one embodiment, the upper package 60, 900 may include a package substrate 605 and a second semiconductor die 620 attached to the package substrate 605, and the forming of the thermally conductive underfill layer 50 may include substantially filling a gap between the package substrate 605 and the backside metal film 129. In one embodiment, the attaching of the upper package 60, 900 to the lower package 10 may include electrically coupling the second semiconductor die 620 to the lower package 10 through the package substrate 605.

Referring now to FIGS. 1A-6, a semiconductor device may include a lower package 10 including a frontside redistribution layer (RDL) structure 110, a lower encapsulation layer 140 on the frontside RDL structure 110, a plurality of through-vias 145 in the lower encapsulation layer 140, and a first semiconductor die 120 adjacent the plurality of through-vias 145 in the lower encapsulation layer 140, wherein the first semiconductor die 120 may include a backside metal film 129 including an upper surface substantially coplanar with an upper surface of the lower encapsulation layer 140 and an upper surface of the plurality of through-vias 145, an upper package 60, 900 stacked on the lower package 10 and including a package substrate 605 including a plurality of metal interconnect structures 617, an upper encapsulation layer 640 on the package substrate 605, a dynamic random access memory (DRAM) die 620 mounted on the package substrate 605 in the upper encapsulation layer 640, and a plurality of bonding wires in the upper encapsulation layer 640 and electrically coupling the DRAM die to the plurality of metal interconnect structures 617, and a thermally conductive underfill layer 50 between the lower package 10 and the upper package 60, 900 and contacting the backside metal film 129.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a lower package comprising a first semiconductor die including a backside metal film on a backside of the first semiconductor die;
an upper package attached to the lower package and electrically coupled to the lower package; and
a thermally conductive underfill layer between the lower package and the upper package and contacting the backside metal film.

2. The package structure of claim 1, wherein the backside metal film has a thermal conductivity greater than 20 W/m·K.

3. The package structure of claim 1, wherein the backside metal film comprises a sintered metal film including metal particles.

4. The package structure of claim 3, wherein the metal particles have a width in a first direction less than 100 μm, and a length in a second direction perpendicular to the first direction less and 100 μm.

5. The package structure of claim 4, wherein the metal particles comprise at least one of copper, silver, aluminum or gold.

6. The package structure of claim 1, wherein the backside metal film has a thickness less than or equal to 20 μm.

7. The package structure of claim 1, wherein the first semiconductor die further comprises a semiconductor layer and the backside metal film is attached to the semiconductor layer.

8. The package structure of claim 7, wherein a width of the backside metal film in a first direction is less than or equal to a width of the semiconductor layer in the first direction, and a length of the backside metal film in a second direction perpendicular to the first direction is less than or equal to a length of the semiconductor layer in the second direction.

9. The package structure of claim 1, wherein the lower package further comprises a lower encapsulation layer and the first semiconductor die is in the lower encapsulation layer such that an upper surface of the backside metal film is substantially coplanar with an upper surface of the lower encapsulation layer.

10. The package structure of claim 1, wherein the thermally conductive underfill layer comprises epoxy resin and metal particles dispersed in the epoxy resin.

11. The package structure of claim 1, wherein the thermally conductive underfill layer has a thermal conductivity greater than 20 W/m·K.

12. The package structure of claim 1, wherein the upper package comprises a package substrate and a second semiconductor die attached to the package substrate and electrically coupled to the lower package through the package substrate.

13. The package structure of claim 12, wherein the lower package further comprises a frontside redistribution layer (RDL) structure and a through via adjacent the first semiconductor die on the frontside RDL structure, and the second semiconductor die comprises a dynamic random access memory (DRAM) die electrically coupled to the frontside RDL structure by the through via.

14. The package structure of claim 12, wherein the thermally conductive underfill layer has a thickness greater than a thickness of the backside metal film and substantially fills a space between the package substrate and the backside metal film.

15. A method of making a package structure, the method comprising:
forming a first semiconductor die including a backside metal film on a backside of the first semiconductor die;
forming a lower package including the first semiconductor die;
attaching an upper package to the lower package; and
forming a thermally conductive underfill layer between the lower package and the upper package such that the thermally conductive underfill layer contacts the backside metal film in the lower package.

16. The method of claim 15, wherein the backside metal film comprises a sintered metal film and the forming of the backside metal film comprises:
forming a metal film material layer including a plurality of metal particles on a backside surface of the first semiconductor die; and
heating the metal film material layer to form the sintered metal film.

17. The method of claim 15, wherein the first semiconductor die further comprises a semiconductor layer and the forming of the backside metal film comprises forming the backside metal film on the semiconductor layer such that a width of the backside metal film in a first direction is less than or equal to a width of the semiconductor layer in the first direction, and a length of the backside metal film in a second direction perpendicular to the first direction is less than or equal to a length of the semiconductor layer in the second direction.

18. The method of claim 15, wherein the upper package comprises a package substrate and a second semiconductor die attached to the package substrate, and the forming of the thermally conductive underfill layer comprises substantially filling a gap between the package substrate and the backside metal film.

19. The method of claim 18, wherein the attaching of the upper package to the lower package comprises electrically coupling the second semiconductor die to the lower package through the package substrate.

20. A semiconductor device, comprising:
a lower package comprising:
a frontside redistribution layer (RDL) structure;
a lower encapsulation layer on the frontside RDL structure;
a plurality of through vias in the lower encapsulation layer; and
a first semiconductor die adjacent the plurality of through-vias in the lower encapsulation layer, wherein the first semiconductor die comprises a backside metal film including an upper surface substantially coplanar with an upper surface of the lower encapsulation layer and an upper surface of the plurality of through vias;
an upper package stacked on the lower package and comprising:
a package substrate including a plurality of metal interconnect structures;
an upper encapsulation layer on the package substrate;
a dynamic random access memory (DRAM) die mounted on the package substrate in the upper encapsulation layer; and
a plurality of bonding wires in the upper encapsulation layer and electrically coupling the DRAM die to the plurality of metal interconnect structures; and
a thermally conductive underfill layer between the lower package and the upper package and contacting the backside metal film.
